(19) United States
(12) Patent Application Publication
(10) Pub. No.: US 2024/0379913 A1
(43) Pub. Date: Nov. 14, 2024

(54) DISPLAY DEVICE

(71) Applicant: Samsung Display Co., LTD., Yongin-si (KR)

(72) Inventors: Che Ho LIM, Yongin-si (KR); Kang Uk KIM, Yongin-si (KR); Ho-Yong SHIN, Yongin-si (KR); Kwang-Min LEE, Yongin-si (KR); Kang Soo HAN, Yongin-si (KR); Seok-Joon HONG, Yongin-si (KR)

(21) Appl. No.: 18/406,150

(22) Filed: Jan. 6, 2024

(30) Foreign Application Priority Data
May 11, 2023 (KR) 10-2023-0061044

(51) Int. Cl. H01L 33/50; H01L 25/075; H01L 25/16; H01L 33/62

(52) U.S. Cl. CPC H01L 33/505; H01L 25/0753; H01L 25/167; H01L 33/62

(57) ABSTRACT

A display device includes a substrate including a display area and a non-display area, a transistor disposed on the substrate, a light emitting diode electrically connected to the transistor, a color conversion layer and a transmission layer disposed on the light emitting diode, and a partition wall disposed on the light emitting diode, where the partition wall includes a first partition wall disposed in the display area between the color conversion layer and the transmission layer and a second partition wall disposed in the non-display area, and the partition wall includes a first part having a first length from a first end to a boundary of the display area and the non-display area, and a second part having a second length from a second end to a boundary of the display area and the non-display area, where the first length is greater than the second length.

This application claims priority to Korean Patent Application No. 10-2023-0061044, filed on May 11, 2023, and all the benefits accruing therefrom under 35 U.S.C. § 119, the content of which in its entirety is herein incorporated by reference.

### BACKGROUND

### (a) Field

The disclosure relates to a display device.

### (b) Description of the Related Art

A light emitting diode is an element in which holes supplied from an anode and electrons supplied from a cathode are combined in an emission layer formed between the anode and the cathode to form excitons, and these excitons are stabilized to emit light.

Since the light emitting diode has various desired features such as a wide viewing angle, fast response speed, thin thickness, and low power consumption, the light emitting diode is widely applied to various electric and electronic devices such as televisions, monitors, and mobile phones.

Recently, a display device including a color conversion layer has been proposed to implement a high-efficiency display device.

The color conversion layer may convert incident light into light of a different color.

### SUMMARY

Embodiments are intended to provide a display device in which stains do not appear at the edge of a display area by providing a filling layer having a uniform thickness.

A display device according to an embodiment includes a substrate including a display area and a non-display area, a transistor disposed on the substrate, a light emitting diode disposed on the transistor and electrically connected to the transistor, a color conversion layer and a transmission layer disposed on the light emitting diode, and a partition wall disposed on the light emitting diode, where the partition wall includes a first partition wall disposed in the display area between the color conversion layer and the transmission layer and a second partition wall disposed in the non-display area. In such an embodiment, the partition wall includes a first part having a first length from a first end to a boundary of the display area and the non-display area, and a second part having a second length from a second end to the boundary of the display area and the non-display area, where the first length is greater than the second length.

In an embodiment, the first part may protrude further than the second part from the boundary of the display area and the non-display area in a plan view.

In an embodiment, the first partition wall may define a first opening in which the color conversion layer and the transmission layer are disposed, and the second partition wall may define a second opening having a same shape as the first opening.

In an embodiment, the first part and the second part may protrude from the boundary of the display area and the non-display area toward a first direction.

In an embodiment, the first part and the second part may be alternately disposed along a second direction perpendicular to the first direction.

In an embodiment, the display device may further include a color filter disposed on the color conversion layer, the transmission layer and the partition wall.

In an embodiment, the color filter includes a first color filter disposed on the transmission layer, a second color filter disposed on a second color conversion layer of the color conversion layer, and a third color filter a first color conversion layer of the color conversion layer, and the partition wall may overlap at least two selected from the first color filter, the second color filter, and the third color filter.

In an embodiment, the first color filter, the second color filter, and the third color filter may continuously extend in the non-display area.

In an embodiment, the display device may further include a filling layer disposed between the light emitting diode and the color conversion layer, and between the light emitting diode and the transmission layer.

In an embodiment, the filling layer may fill the second opening.

In an embodiment, The display device may further include a column spacer disposed between the partition wall and the light emitting diode.

In an embodiment, the first partition wall may define a first opening in which the color conversion layer and the transmission layer are positioned, and no opening may be defined in the second partition wall.

In an embodiment, the second partition wall may continuously overlap the color filter positioned in the non-display area.

In an embodiment, the display device may further include a filling layer disposed on the partition wall, the color conversion layer, and the transmission layer, and a color filter disposed on the filling layer.

A display device according to an embodiment includes a first substrate including a display area and a non-display area, a transistor disposed on the first substrate, a light emitting diode disposed on the first substrate and electrically connected to the transistor, a color conversion layer disposed on the light emitting diode, a transmissive layer, and the partition wall disposed on the light emitting diode, where the partition wall includes the first partition wall disposed in the display area between the color conversion layer and the transmissive layer and the second partition wall disposed in the non-display area, the second partition wall includes a protruding part and a recessed part in a plan view.

In an embodiment, the display device may further include an encapsulation layer disposed on the light emitting diode and the filling layer disposed between the color conversion layer and the encapsulation layer, where the filling layer may fill the recessed part.

In an embodiment, the first partition wall may define a first opening overlapping the color conversion layer and the transmission layer, and the second partition wall may define a second opening having the same shape as the first opening.

In an embodiment, the first partition wall may define the first opening overlapping the color conversion layer and the transmission layer, and no opening may be defined in the second partition wall.

In an embodiment, the display device may further include a second substrate overlapping the first substrate and a color filter disposed between the second substrate and the color conversion layer.

In an embodiment, the display device may further include a filling layer disposed between the color filter and the color conversion layer.

According to embodiments, a display device having improved display quality and controlling stains at the edge of a display area by providing a filling layer having a uniform thickness may be provided.

### BRIEF DESCRIPTION OF THE DRAWINGS

FIG. 1 is a schematic exploded perspective view of a display device according to an embodiment.

FIG. 2 is a schematic cross-sectional view of a display panel according to an embodiment.

FIG. 3 is a schematic top plan view of the display panel according to an embodiment.

FIG. 4 is a cross-sectional view of the display panel according to the embodiment of FIG. 3.

FIG. 5 is a cross-sectional view of the display panel according to the embodiment of FIG. 3.

FIG. 6 is a schematic top plan view of the display panel according to an embodiment.

FIG. 7 is a schematic cross-sectional view of the display panel according to the embodiment of FIG. 6.

FIG. 8 is a schematic cross-sectional view of the display panel according to the embodiment of FIG. 6.

FIG. 9 is a cross-sectional view of a display panel according to an alternative embodiment of FIG. 3.

FIG. 10 is a cross-sectional view of a display panel according to an alternative embodiment of FIG. 6.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

In addition, when a part such as a layer, film, region, or plate is said to be “above” or “on” another part, this includes not only the case where it is “directly on” the other part, but also the case where another part exists in the middle thereof.

Conversely, when a part is said to be “directly on” another part, it means that there is no other part in between.

In addition, being “above” or “on” a reference part means being positioned above or below the reference part, and does not necessarily mean being positioned “above” or “on” it in the opposite direction of gravity.

Also, throughout the specification, when reference is made to “planar image,” it means when the target part is viewed from above, and when reference is made to “cross-sectional image,” it means when the cross section of the target part cut vertically is viewed from the side.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

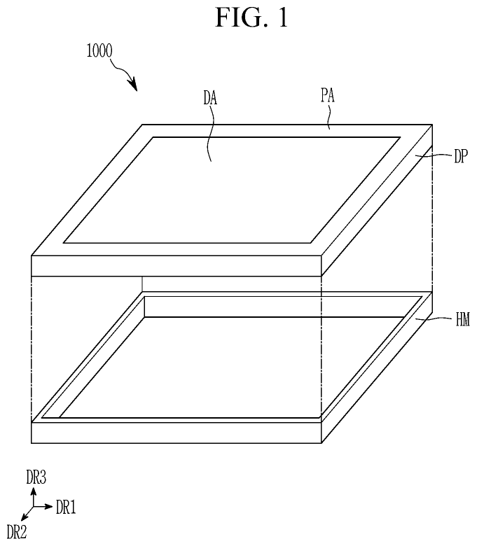

Hereinafter, a display device according to an embodiment will be described with reference to FIG. 1.

FIG. 1 is a schematic exploded perspective view of the display device according to an embodiment.

Referring to FIG. 1, the display device 1000 according to an embodiment may include a display panel DP and a housing HM.

One surface of the display panel DP on which an image is displayed is parallel to a surface defined by first and second directions R1 and DR2.

A third direction DR3 indicates a normal direction of one surface on which an image is displayed, that is, a thickness direction of the display panel DP.

The front (or upper surface) and rear surface (or lower surface) of each member are divided by the third direction DR3.

However, directions indicated by the first to third directions DR1, DR2, and DR3 may be converted into other directions in a relative concept.

The display panel DP may be a flat rigid display panel, but is not limited thereto and may also be a flexible display panel.

In an embodiment, the display panel DP may be an organic light emitting display panel.

However, the type of display panel DP is not limited thereto, and may include various types of panels.

In an embodiment, for example, the display panel DP may be a liquid crystal display panel, an electrophoretic display panel, an electrowetting display panel, or the like.

Alternatively, the display panel DP may be a next-generation display panel such as a micro light emitting diode (LED) display panel, a quantum dot LED display panel, and a quantum dot organic LED display panel.

A micro LED display panel is formed in such a way that each pixel is constituted by LEDs having a size of 10 micrometers to 100 micrometers.

Such a micro LED display panel has merits such as the use of inorganic materials, omission of a backlight, fast response speed, high luminance with low power consumption, and non-breaking when bent.

A quantum dot LED display panel is formed by attaching a film containing quantum dots or forming a material containing quantum dots.

Quantum dots are composed of inorganic materials such as indium and cadmium, and refer to particles that emit light by themselves and have a diameter of several nanometers or less.

By adjusting the particle size of the quantum dots, light of a desired color can be displayed.

The quantum dot organic LED display panel uses a blue organic LED as a light source, attaches a film containing red and green quantum dots on it, or deposits a material containing red and green quantum dots to realize color.

The display panel DP according to an embodiment may include various other display panels.

As shown in FIG. 1, the display panel DP includes a display area DA where an image is displayed and a non-display area PA adjacent to the display area DA.

The non-display area PA is a region where no image is displayed.

The display area DA may have a rectangular shape, for example, and the non-display area PA may have a shape surrounding the display area DA.

However, the shapes of the display area DA and the non-display area PA may be relatively designed without being limited thereto.

The housing HM provides a predetermined inner space.

The display panel DP is mounted inside the housing HM.

In addition to the display panel DP, various electronic components such as a power supply unit, a storage device, and an audio input/output module may be mounted inside the housing HM.

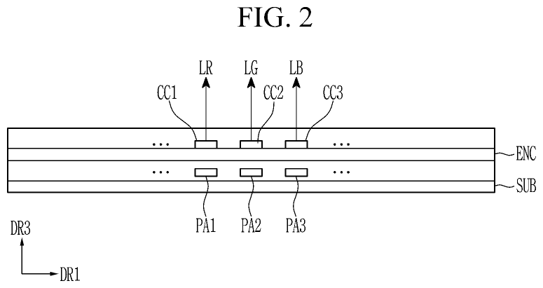

Hereinafter, a display area of a display panel according to an embodiment will be described with reference to FIG. 2.

FIG. 2 is a schematic cross-sectional view of a display panel according to an embodiment.

Referring to FIG. 2, a plurality of pixels PA1, PA2, and PA3 may be disposed or formed on the substrate SUB corresponding to the display area DA of FIG. 1.

Each of the pixels PA1, PA2, and PA3 may include a plurality of transistors and a light emitting element connected thereto.

An encapsulation layer ENC may be positioned on the plurality of pixels PA1, PA2, and PA3.

The display area DA may be protected from outside air or moisture through the encapsulation layer ENC.

The encapsulation layer ENC may be integrally provided to overlap the entire surface of the display area DA, and may also be partially disposed on the non-display area PA.

A first color conversion part CC1, a second color conversion part CC2, and a transmission part CC3 may be positioned on the encapsulation layer ENC.

The first color conversion part CC1 overlaps the first pixel PA1, the second color conversion part CC2 overlaps the second pixel PA2, and the transmission part CC3 overlaps the third pixel PA3.

Light emitted from the first pixel PA1 may pass through the first color conversion unit CC1 to provide red light LR.

Light emitted from the second pixel PA2 may pass through the second color conversion unit CC2 to provide green light LG.

Light emitted from the third pixel PA3 may pass through the transmission part CC3 to provide blue light LB.

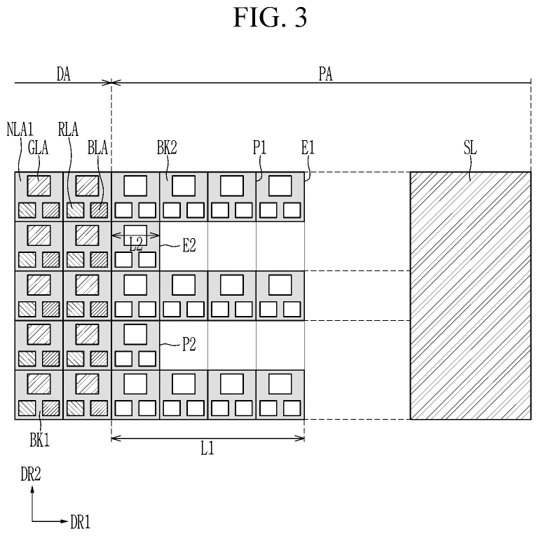

Hereinafter, a structure of the display panel according to an embodiment will be described in greater detail with reference to FIG. 3 to FIG. 5.

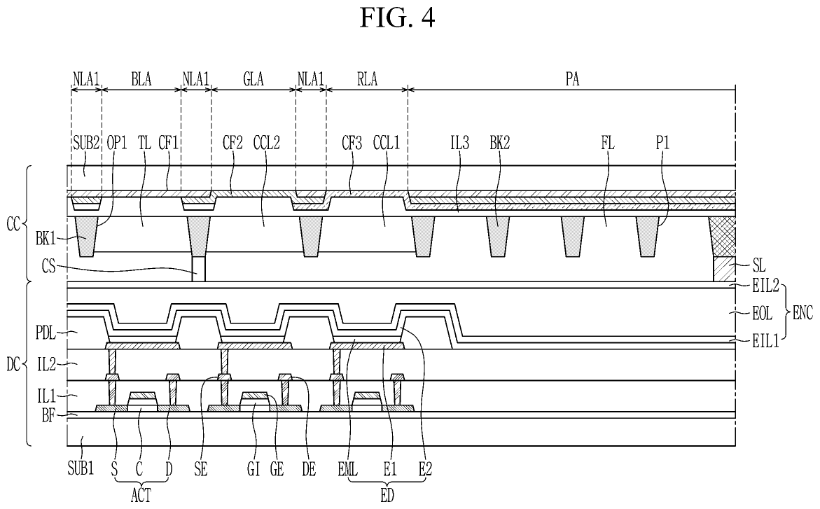

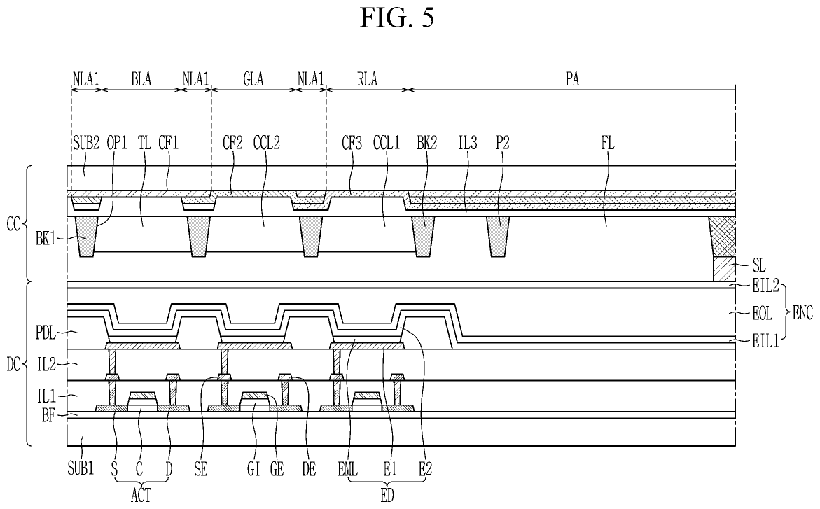

FIG. 3 is a schematic top plan view of the display panel according to an embodiment, FIG. 4 is a cross-sectional view of the display panel according to the embodiment of FIG. 3, and FIG. 5 is a cross-sectional view of the display panel according to the embodiment of FIG. 3.

Referring first to FIG. 3, the display area DA according to an embodiment includes a red light emitting region RLA, a green light emitting region GLA, and a blue light emitting region BLA.

A non-emission region NLA1 may be positioned between the red light emitting region RLA, the green light emitting region GLA, and the blue light emitting region BLA.

Each light emitting region may correspond to a pixel.

In an embodiment, for example, the blue light emitting region BLA, the red light emitting region RLA, and the green light emitting region GLA may correspond to a blue pixel, a red pixel, and a green pixel, respectively.

Although each light emitting region is shown as a rectangle in a plan view, it may have other shapes such as a rhombus, a pentagon, and an octagon, and may have various shapes and areas according to embodiments.

Referring to FIG. 3 and FIG. 4, the cross-sectional structure of the display area DA will be described.

The display unit DC according to an embodiment includes a first substrate SUB1.

The first substrate SUB1 may include a flexible material such as plastic that can be easily bent, folded, or rolled.

A buffer layer BF may be positioned on the first substrate SUB1.

The buffer layer BF may include silicon nitride SiNx, silicon oxide SiO2, or silicon oxynitride.

In an embodiment, the buffer layer BF is positioned between the first substrate SUB1 and the semiconductor layer ACT to block impurities from the first substrate SUB1 during a crystallization process to form polycrystalline silicon, thereby improving the characteristics of the polycrystalline silicon, and stress of the semiconductor layer ACT formed on the buffer layer BF may be relieved by planarizing the first substrate SUB1.

In an embodiment, the semiconductor layer ACT is positioned on the buffer layer BF.

The semiconductor layer ACT may include or be formed of polycrystalline silicon or an oxide semiconductor.

The semiconductor layer ACT may include a channel region C, a source region S, and a drain region D.

In an embodiment, source region S and the drain region D are disposed or defined on opposing sides of the channel region C.

The channel region C is an intrinsic semiconductor not doped with impurities, and the source region S and drain region D are impurity semiconductors doped with conductive impurities.

The semiconductor layer ACT may include or be formed of an oxide semiconductor, and in this case, a passivation layer (not shown) may be added to protect the oxide semiconductor material that is vulnerable to an external environment such as high temperature.

In an embodiment, a gate insulating layer GI is positioned on the semiconductor layer ACT.

The gate insulating layer GI may be a single layer or a multi-layer including at least one selected from silicon nitride SiNx, silicon oxide SiO2, and silicon oxynitride.

In an embodiment, a gate electrode GE is positioned on the gate insulating layer GI, the gate electrode GE includes at least one selected from copper Cu, a copper alloy, aluminum Al, an aluminum alloy, molybdenum Mo, and a molybdenum alloy.

In an embodiment, an interlayer insulating layer IL1 is positioned on the gate electrode GE and the gate insulating layer GI.

The interlayer insulating layer IL1 may include silicon nitride (SiNx), silicon oxide (SiO₂), or silicon oxynitride.

An opening exposing the source region S and the drain region D may be defined or formed in the interlayer insulating layer IL1.

In an embodiment, a source electrode SE and a drain electrode DE are positioned on the interlayer insulating layer IL1.

The source electrode SE and the drain electrode DE may be connected to the source region S and the drain region D, respectively, of the semiconductor layer ACT through the opening defined or formed in the interlayer insulating layer IL1.

In an embodiment, a passivation layer IL2 is positioned on the interlayer insulating layer IL1, the source electrode SE, and the drain electrode DE.

In such an embodiment, the passivation layer IL2 covers and flattens the interlayer insulating layer IL1, the source electrode SE, and the drain electrode DE, such that the first electrode E1 may be formed on the passivation layer IL2 without a step.

The passivation layer IL2 may include or be made of an organic material such as polyacrylate resin or polyimide resin, or a laminated film of an organic material and an inorganic material.

The first electrode E1 may be positioned on the passivation layer IL2.

The first electrode E1 may be connected to the drain electrode DE through the opening of the passivation layer IL2.

The driving transistor including the gate electrode GE, the semiconductor layer ACT, the source electrode SE, and the drain electrode DE may be connected to the first electrode E1 to supply a driving current to a light emitting element ED.

In addition to the driving transistor shown in FIG. 4, the display device according to an embodiment may further include a switching transistor not shown connected to a data line for transmitting a data voltage in response to a scan signal and connected to a driving transistor and being driven in response to the scan signal. A compensation transistor not shown for compensating the threshold voltage of the transistor may be further included.

A pixel defining layer PDL may be positioned on the passivation layer IL2 and the first electrode E1, and the pixel defining layer PDL may be provided with a pixel opening overlapping the first electrode E1 to define an emission region.

The pixel defining layer PDL may include an organic material such as polyacrylate resin or polyimide resin or a silica-based inorganic material.

The pixel opening may have a planar shape substantially similar to that of the first electrode E1 and may have a planar diamond shape or an octagonal shape similar to the diamond shape, but is not limited thereto and may have any shape such as a rectangle or a polygon.

In an embodiment, an emission layer EML is positioned on the first electrode E1 overlapping the pixel opening.

The emission layer EML may include or be formed of a low molecular weight organic material or a high molecular weight organic material such as poly 3,4-ethylenedioxythiophene (PEDOT).

In an embodiment, the emission layer EML is a multilayer including at least two selected from a hole injection layer HIL, a hole transporting layer HTL, an electron transporting layer ETL, and an electron injection layer EIL.

Most of the emission layer EML may be positioned within the pixel opening, and may also be positioned on a side surface or above the pixel defining layer PDL.

In an embodiment, a second electrode E2 is positioned on the emission layer EML.

The second electrode E2 may be positioned over a plurality of pixels, and may receive a common voltage through a common voltage transfer unit not shown in the non-display area.

The first electrode E1, the emission layer EML, and the second electrode E2 may constitute the light emitting element (e.g., an LED) ED.

In an embodiment, the first electrode E1 may be an anode that is a hole injection electrode, and the second electrode E2 may be a cathode that is an electron injection electrode.

However, the embodiments are not necessarily limited thereto, and alternatively, the first electrode E1 may serve as a cathode and the second electrode E2 may serve as an anode according to a driving method of the organic light emitting display device.

Holes and electrons are injected into the emission layer EML from the first electrode E1 and the second electrode E2, respectively, and when the excitons in which the injected holes and electrons fall from the excited state to a ground state, light emission occurs.

In an embodiment, an encapsulation layer ENC is positioned on the second electrode E2.

The encapsulation layer ENC may cover not only the upper surface but also the side surfaces of the display layer including the light emitting element ED, thereby sealing the display layer.

In an embodiment, the light emitting element ED may be very vulnerable to moisture and oxygen, and the encapsulation layer ENC may protect the light emitting element ED by sealing the display layer to block inflow of external moisture and oxygen.

The encapsulation layer ENC may include a plurality of layers, and may include or be formed of a composite layer including both an inorganic layer and an organic layer. The encapsulation layer ENC may include an inorganic layer EIL1, an organic layer EOL, and an inorganic layer EIL2.

In an embodiment, a color conversion unit CC is positioned on the encapsulation layer ENC.

The color conversion unit CC includes a second substrate SUB2 opposite to the first substrate SUB1.

The second substrate SUB2 may include a flexible material such as plastic that can be easily bent, folded, or rolled.

The color conversion unit CC may include a first color filter CF1, a second color filter CF2, and a third color filter CF3 positioned between the second substrate SUB2 and the display unit DC.

The third color filter CF3 may overlap the first color conversion layer CCL1 to be described later.

The third color filter CF3 transmits the red light that has passed through the first color conversion layer CCL1 and absorbs light of other wavelengths, thereby increasing the purity of the red light emitted to the outside of the display device.

The second color filter CF2 may overlap the second color conversion unit CCL2. The second color filter CF2 transmits the green light that has passed through the second color conversion layer CCL2 and absorbs light of other wavelengths, thereby increasing the purity of the green light emitted to the outside of the display device.

The first color filter CF1 may overlap the transmission part TL. The first color filter CF1 transmits the blue light that has passed through the transmission layer TL and absorbs light of other wavelengths, thereby increasing the purity of the blue light emitted to the outside of the display device.

At least two selected from the third color filter CF3, the second color filter CF2, and the first color filter CF1 may overlap each other in the non-emission area NLA1 to serve as a light blocking layer.

The non-emission area NLA1 may overlap the pixel defining layer PDL of the display unit DC.

An insulating layer IL3 may be positioned between the first color filter CF1, the second color filter CF2, the third color filter CF3, and the display unit DC. The insulating layer IL3 may include silicon oxide, silicon nitride, or silicon oxynitride.

A first partition wall BK1 may be positioned between the display parts DC and the insulating layer IL3. The first partition wall BK1 may define a first opening OP1 overlapping the pixel opening.

A first color conversion layer CCL1, a second color conversion layer CCL2, and a transmission layer TL may be positioned in the first opening OP1.

The first color conversion layer CCL1 may convert supplied light (or light incident thereto) into red light. The first color conversion layer CCL1 may include quantum dots.

The second color conversion layer CCL2 may convert supplied light into green light. The second color conversion layer CCL2 may include quantum dots.

The quantum dots will be described in detail below.

In the specification, quantum dots (hereinafter referred to as semiconductor nanocrystals) are group II-VI compounds, group III-V compounds, group IV-VI compounds, group IV elements or compounds, group I-III-VI compounds, a group II-III-VI compound, a group I-II-IV-VI compound, or a combination thereof.

The group II-VI compound is a binary element compound selected from CdSe, CdTe, ZnS, ZnSe, ZnTe, ZnO, HgS, HgSe, HgTe, MgSe, MgS, and mixtures thereof, a ternary compound selected from AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or a quaternary compound selected from HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The group II-VI compound may further include a group III metal.

The group III-V compound is a binary element compound selected from GaN, GaP, GaAs, GaSb, AlN, AlP, AlAs, AlSb, InN, InP, InAs, InSb, and mixtures thereof, a ternary compound selected from GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and mixtures thereof; or a quaternary compound selected from GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and mixtures thereof.

The group III-V compound may further include a group II metal (e.g., InZnP).

The group IV-VI compound is a binary element compound selected from SnS, SnSe, SnTe, PbS, PbSe, PbTe, and mixtures thereof, a ternary compound selected from SnSeS, SnSeTe, SnSTe, PbSeS, PbSeTe, PbSTe, SnPbS, SnPbSe, SnPbTe, and mixtures thereof, ora quaternary compound selected from SnPbSSe, SnPbSeTe, SnPbSTe, and mixtures thereof.

The group IV element or compound is a monoatomic compound selected from Si, Ge, and combinations thereof; or a binary element compound selected from SiC, SiGe, and combinations thereof, but is not limited thereto.

Examples of the group I-III-VI compound include, but are not limited to, CuInSe2, CuInS2, CuInGaSe, and CuInGaS.

Examples of the group I-II-IV-VI compound include, but are not limited to, CuZnSnSe and CuZnSnS.

The group IV element or compound is an element selected from Si, Ge, and mixtures thereof; or a binary element compound selected from SiC, SiGe, and mixtures thereof.

The group II-III-VI compound may be ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe or HgAlTe. The group II-III-VI compound may be selected from HgInTe, MgGaS, MgAlS, MgInS, MgGaSe, MgAlSe, MgInSe, and combinations thereof, but is not limited thereto.

The group I-II-IV-VI compound may be selected from CuZnSnSe and CuZnSnS, but is not limited thereto.

In an embodiment, the quantum dots may not include cadmium.

Quantum dots may include semiconductor nanocrystals based on group III-V compounds including indium and phosphorus.

The group III-V compound may further include zinc.

Quantum dots may include semiconductor nanocrystals based on group II-VI compounds including zinc and a chalcogen element (e.g., sulfur, selenium, tellurium, or combinations thereof).

In the quantum dots, the above-mentioned two-element compound, three-element compound, and/or quaternary element compound may be present in a particle at a uniform concentration, or may be present in a same particle with partially different concentration distributions.

Also, one quantum dot may have a core/shell structure surrounding another quantum dot.

The interface between the core and the shell may have a concentration gradient in which the concentration of elements present in the shell decreases toward the center.

In some embodiments, the quantum dot may have a core-shell structure including a core including the aforementioned nanocrystal and a shell surrounding the core.

The shell of the quantum dots may serve as a protective layer for maintaining semiconductor properties by preventing chemical denaturation of the core and/or as a charging layer for imparting electrophoretic properties to the quantum dots.

The shell may be a monolayer or a multilayer.

The interface between the core and the shell may have a concentration gradient in which the concentration of elements present in the shell decreases toward the center.

Examples of the quantum dot shell include metal or non-metal oxides, semiconductor compounds, or combinations thereof.

For example, the metal or nonmetal oxide may be SiO₂, Al₂O₃, TiO₂, ZnO, MnO, Mn₂O₃, Mn₃O₄, CuO, FeO, Fe₂O₃, Fe₃O₄, CoO, CO₃O₄, NiO, or a binary element compound such as MgAl₂O₄, CoFe₂O₄, or NiFe₂O₄. CoMn₂O₄ and the like, but the invention is not limited thereto.

In addition, examples of the semiconductor compound include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and the like. However, the invention is not limited thereto.

The interface between the core and the shell may have a concentration gradient in which the concentration of elements present in the shell decreases toward the center.

In addition, the semiconductor nanocrystal may have a structure including a single semiconductor nanocrystal core and a multi-layered shell surrounding the semiconductor nanocrystal core.

In an embodiment, the multi-layered shell can have two or more layers, such as two, three, four, five, or more layers.

Two adjacent layers of the shell may have a single composition or different compositions.

Each layer in the multi-layered shell may have a composition that varies along a radius.

Quantum dots may have a full width of half maximum (FWHM) of the emission wavelength spectrum of about 45 nanometers (nm) or less, for example about 40 nm or less, or about 30 nm or less, and color purity or color reproducibility in this range can improve.

In addition, since light emitted through the quantum dots is emitted in all directions, a wide viewing angle may be improved.

In the quantum dots, the shell material and the core material may have different energy band gaps.

For example, the energy bandgap of the shell material may be larger than that of the core material.

In other embodiments, the energy band gap of the shell material may be smaller than that of the core material.

The quantum dots may have multi-layered shells.

In a multi-layered shell, the energy band gap of the outer layers may be larger than that of the inner layers (i.e., layers closer to the core).

In a multi-layered shell, the energy band gap of the outer layer may be smaller than that of the inner layer.

Quantum dots can control the absorption/emission wavelength by adjusting the composition and size.

The maximum emission peak wavelength of the quantum dots may have a wavelength range of ultraviolet to infrared wavelengths or higher.

Quantum dots can have a quantum efficiency of about 10% or greater, such as about 30% or greater, about 50% or greater, about 60% or greater, about 70% or greater, about 90% or greater, or even 100%.

Quantum dots can have a relatively narrow spectrum.

The quantum dots may have, for example, a full width at half maximum of an emission wavelength spectrum of about 50 nm or less, such as about 45 nm or less, about 40 nm or less, or about 30 nm or less.

The quantum dots may have a particle size of about 1 nm or greater and about 100 nm or less.

The size of the particle refers to the diameter of the particle or a diameter converted from a two-dimensional image obtained by transmission electron microscopy assuming a spherical shape.

The quantum dots may have a size of about 1 nm to about 20 nm, such as 2 nm or greater, 3 nm or greater, or 4 nm or greater and 50 nm or less, 40 nm or less, 30 nm or less, 20 nm or less, 15 nm or less, such as 10 nm or less.

The shape of the quantum dots is not particularly limited.

For example, the shape of the quantum dots may include a sphere, a polyhedron, a pyramid, a multipod, a square, a cuboid, a nanotube, a nanorod, a nanowire, a nanosheet, or a combination thereof, but is not limited thereto.

Quantum dots are commercially available or can be suitably synthesized.

The particle size of the quantum dots can be controlled relatively freely, and the particle size can be uniformly controlled during colloidal synthesis.

The quantum dots may include an organic ligand (e.g., having a hydrophobic moiety and/or a hydrophilic moiety).

The organic ligand moiety may be bound to the surface of the quantum dot.

The organic ligand includes RCOOH, RNH₂, R₂NH, R₃N, RSH, R₃PO, R₃P, ROH, RCOOR, RPO(OH)₂, RHPOOH, R₂POOH, or a combination thereof. Each R is independently C3 to C40 (e.g., C5 or more and C24 or less) substituted or unsubstituted alkyl, substituted or unsubstituted alkenyl, C3 to C40 substituted or unsubstituted aliphatic hydrocarbon group, substituted or unsubstituted C6 to C40 aryl group, a substituted or unsubstituted aromatic hydrocarbon group of C6 to C40 (e.g., C6 or more and C20 or less), or a combination thereof.

Examples of the organic ligand include thiol compounds such as methane thiol, ethane thiol, propane thiol, butane thiol, pentane thiol, hexane thiol, octane thiol, dodecane thiol, hexadecane thiol, octadecane thiol, and benzyl thiol; methane amine, ethane amine, propane amine, butane amine, pentyl amine, hexyl amine, octyl amine, nonylamine, decylamine, dodecyl amine, hexadecyl amine, octadecyl amine, dimethyl amine, diethyl amine, dipropyl amine, amines such as tributylamine and trioctylamine; carboxylic acid compounds such as methane acid, ethanoic acid, propanoic acid, butanoic acid, pentanoic acid, hexanoic acid, heptanoic acid, octanoic acid, dodecanoic acid, hexadecenoic acid, octadecanoic acid, oleic acid, and benzoic acid; phosphine compounds such as methyl phosphine, ethyl phosphine, propyl phosphine, butyl phosphine, pentyl phosphine, octylphosphine, dioctylphosphine, tributylphosphine, and trioctylphosphine; phosphines such as methyl phosphine oxide, ethyl phosphine oxide, propyl phosphine oxide, butyl phosphine oxide, pentyl phosphine oxide, tributylphosphine oxide, octylphosphine oxide, dioctyl phosphine oxide, and trioctylphosphine oxide compound or its oxide compound; diphenyl phosphine, triphenyl phosphine compounds or oxide compounds thereof; C5 to C20 alkyl phosphinic acids such as hexylphosphinic acid, octylphosphinic acid, dodecanephosphinic acid, tetradecanephosphinic acid, hexadecanephosphinic acid and octadecanephosphinic acid, C5 to C20 alkyl phosphonic acids; and the like, but are not limited thereto.

The quantum dots may include a hydrophobic organic ligand alone or a mixture of one or more.

The hydrophobic organic ligand may not include a photopolymerizable moiety (e.g., an acrylate group or a methacrylate group).

The transmission layer TL may be positioned in a part corresponding to the blue emission region in the region partitioned by the first partition wall BK1. The transmission layer TL may include a scattering material.

The scattering material may be at least one selected from SiO₂, BaSO₄, Al₂O₃, ZnO, ZrO₂ and TiO₂. The transmission layer TL may include a polymer resin and a scattering material included in the polymer resin. In an embodiment, for example, the transmission layer TL may include TiO₂, but is not limited thereto.

The transmission layer TL may transmit light incident from the light emitting element ED.

In the display panel according to an embodiment, the first color conversion layer CCL1 color-converts (i.e., coverts the color of) the incident light to red light and emits the red light. In addition, the second color conversion layer CCL2 color-converts incident light to green light and emits the green light. However, light incident on the transmission layer TL is transmitted without color conversion.

Incident light may include blue light. The incident light may be blue light alone or a mixture of blue light and green light. Alternatively, Incident light may include blue light, green light, and red light.

A filling layer FL may be positioned between the first color-changing layer CCL1 and the display unit DC, between the second color-changing layer CCL2 and the display unit DC, and between the transmission layer TL and the display unit DC. The filling layer FL may couple the color conversion unit CC and the display unit DC. Also, a column spacer CS may be positioned between the first partition wall BK1 and the encapsulation layer ENC. The column spacer CS may be provided on the encapsulation layer ENC or on the first partition wall BK1.

The column spacer CS may maintain a gap between the display unit DC and the color conversion unit CC.

Hereinafter, the non-display area PA will be described with reference to FIG. 3 and FIG. 4.

In the non-display area PA, a buffer layer BF positioned on the first substrate SUB1, an interlayer insulating layer IL1, a passivation layer IL2, a second electrode E2, and an encapsulation layer ENC extending from the display area DA are positioned thereon.

The display unit DC and the color conversion unit CC may be coupled to each other through the sealant SL positioned in the non-display area PA.

In an embodiment, in the non-display area PA, the first color filter CF1, the second color filter CF2, and the third color filter CF3 are disposed to continuously overlap each other between the second substrate SUB2 and the display unit DC, to overlap the entire portion of the non-display area PA.

The first color filter CF1, the second color filter CF2, and the third color filter CF3 may serve as light blocking members to prevent the non-display area PA from being viewed.

In an embodiment, a second partition wall BK2 may be positioned between the insulating layer IL3 and the encapsulation layer ENC. The second partition wall BK2 may include or be formed of a same material as the first partition wall BK1 in a same process. The second partition wall BK2 may include the second opening OP2 having a same shape and a same arrangement as the first opening OP1 included in the first partition wall BK1.

A color conversion layer or transmission layer may be positioned in the first opening OP1, and the filling layer FL may be positioned in the second opening OP2. The above-described filling layer FL may have a shape to fill the second opening OP2.

The second partition wall BK2 may include a first part P1 and a second part P2. The first part P1 is a part that protrudes from the boundary of the display area DA and the non-display area PA to the sealant SL in a plan view, and the second part P2 refers to a part that is more depressed to (or less protrudes from) the display area DA than the first part P1 in a plan view.

In an embodiment, as shown in FIG. 3, the first part P1 may have a first length L1 from the boundary of the display area DA and the non-display area PA to the first end E1. The second part P2 may have a second length L2 from the boundary of the display area DA and the non-display area PA to the second end E2. In such an embodiment, the first length L1 may be greater than the second length L2.

The first part P1 and the second part P2 may be alternately disposed along the second direction DR2. Although FIG. 3 shows an embodiment having a structure in which the first part P1 and the second part P2 are arranged in the order of first part P1/second part P2/first part P1/second part P2/first part P1, the invention is not limited thereto. Alternatively, the first part P1 and the second part P2 may be arranged in the order of second part P2/first part P1/second part P2/first part P1.

According to an embodiment, in a process of combining the display unit DC and the color conversion unit CC, a material (e.g., a filler) for forming the filling layer FL may be applied to the first partition wall BK1 and the second partition wall BK2.

In this process, the filler material is restricted from moving by the second partition wall BK2, and there may be a height difference between the filling layer FL positioned in the non-display area PA and the filling layer FL positioned in the display area DA. This height difference may be expressed or viewed as a stain at the edge of the display area DA.

According to an embodiment, the second partition wall BK2 positioned in the non-display area PA includes the second part P2, since the filler may be allowed to smoothly move even in the non-display area PA to form a uniform thickness of the filling material, it may be possible to provide the filling layer FL having a uniform thickness.

Accordingly, a distance between the display unit DC and the color conversion unit CC may be maintained uniformly, and staining at the edge of the display area DA may be restricted. A display device having improved display quality can be provided.

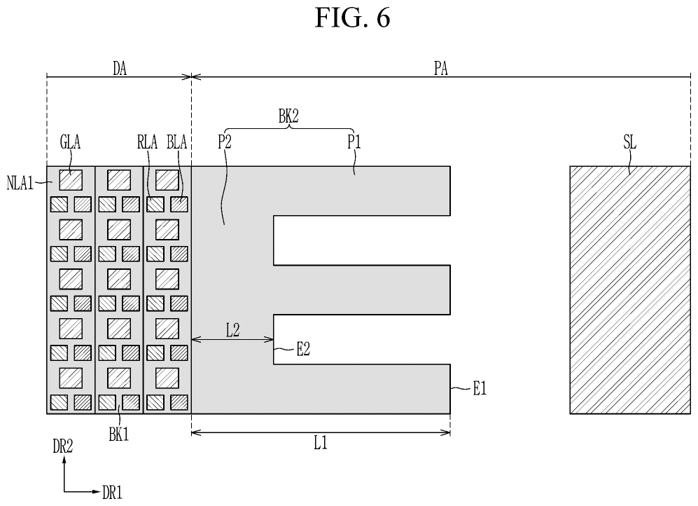

Hereinafter, the display panel according to an embodiment will be described with reference to FIG. 6 to FIG. 8.

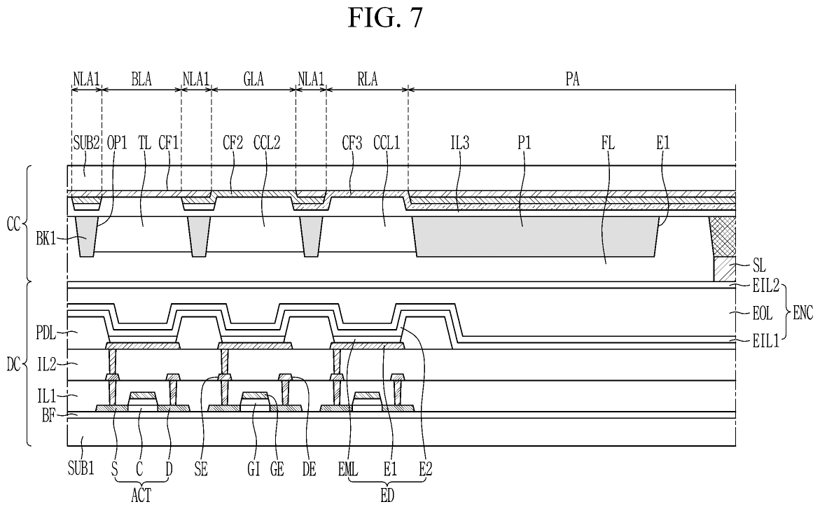

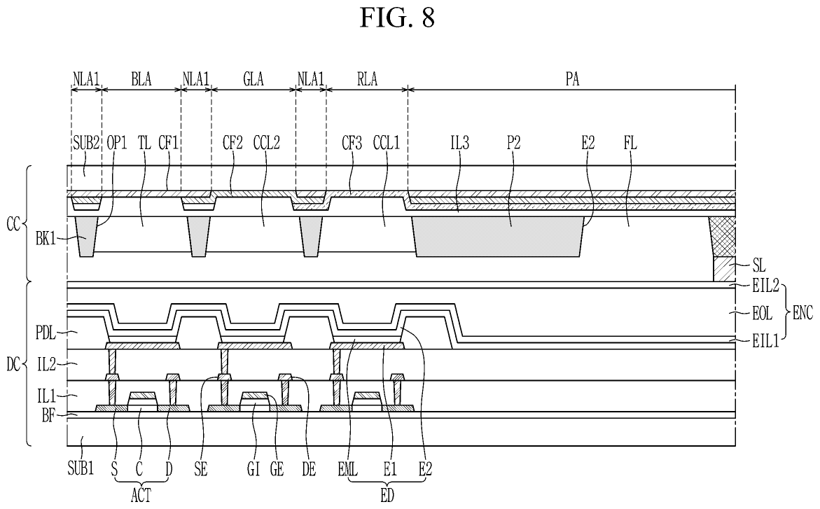

FIG. 6 is a schematic top plan view of a display panel according to an embodiment, FIG. 7 is a schematic cross-sectional view of the display panel according to the embodiment of FIG. 6, and FIG. 8 is a schematic cross-sectional view of the display panel according to the embodiment of FIG. 6. Hereinafter, for convenience of description, any repetitive detailed descriptions of the same or like constituent elements as those described above will be omitted or simplified.

Referring to FIG. 6 to FIG. 8, the second partition wall BK2 according to an embodiment may not be provided with an opening unlike the first partition wall BK1. The second partition wall BK2 may provide one continuous structure in the non-display area PA. The second partition wall BK2 may be provided as a single unitary body.

The second partition wall BK2 may include a first part P1 that protrudes relatively more from the boundary of the display area DA and the non-display area PA, and a second part P2 that protrudes relatively less from the boundary of the display area DA and the non-display area PA. On a plan view, the first part P1 may be a protrusion, and the second part P2 may be a depression.

The first part P1 may have a first length L1 from the boundary of the display area DA and the non-display area PA to the first end E1. The second part P2 may have a second length L2 from the boundary of the display area DA and the non-display area PA to the second end E2. In this case, the first length L1 may be greater than the second length L2.

The first part P1 and the second part P2 may be alternately disposed along the second direction DR2. Although FIG. 6 shows an embodiment having a structure in which the first part P1 and the second part P2 are arranged in the order of first part P1/second part P2/first part P1/second part P2/first part P1, the invention is not limited thereto. Alternatively, the first part P1 and the second part P2 may be arranged in the order of second part P2/first part P1/second part P2/first part P1.

According to an embodiment, in the process of combining the display part DC and the color change part CC, a material (e.g., a filling material) for forming a filling layer FL is provided on the first partition wall BK1 and the second partition wall BK2.

In this process, the movement of the filler may be restricted by the second partition wall BK2, and a height difference may occur between the filling layer FL positioned in the non-display area PA and the filling layer FL positioned in the display area DA.

This height difference may be expressed or viewed as a stain at the edge of the display area DA. According to an embodiment, the second partition wall BK2 positioned in the non-display area PA includes the second part P2, which is further recessed from the non-display area PA compared to the first part P1, and it may be possible to provide the filling layer FL having a uniform thickness by allowing the filler to move smoothly through the second part P2.

Accordingly, a distance between the display unit DC and the color conversion unit CC may be maintained uniformly, and staining at the edge of the display area DA may be restricted.

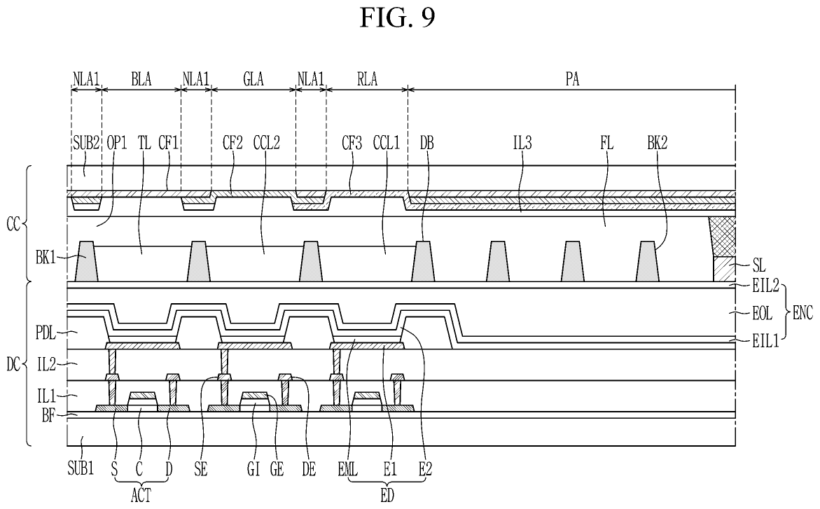

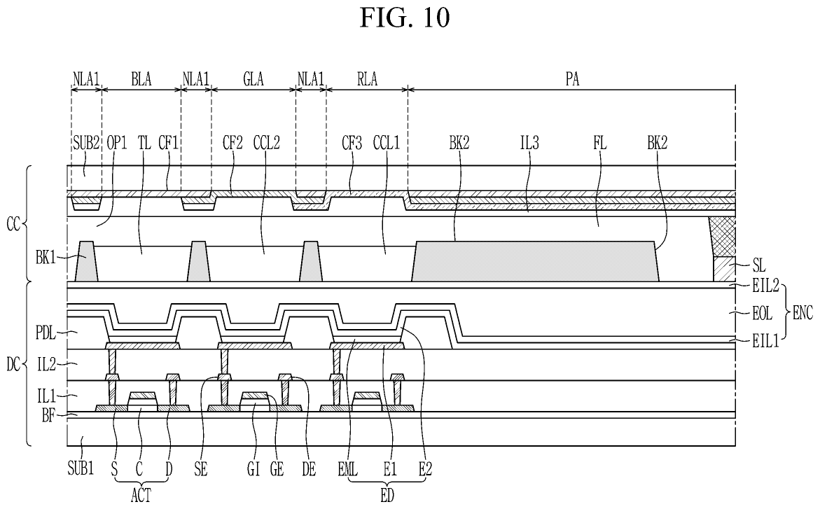

Hereinafter, the display panel according to an alternative embodiment will be described with reference to FIG. 9 and FIG. 10.

FIG. 9 is a cross-sectional view of a display panel according to an alternative embodiment of FIG. 3, and FIG. 10 is a cross-sectional view of a display panel according to an alternative embodiment of FIG. 6. Hereinafter, for convenience of description, any repetitive detailed descriptions of the same or like constituent elements as those described above will be omitted or simplified.

First, FIG. 9 is similar to an embodiment of FIG. 4, but the color conversion unit CC according to the embodiment of FIG. 9 may include a first partition wall BK1 and a second partition wall BK2 positioned on the encapsulation layer ENC.

A first color conversion layer CCL1, a second color conversion layer CCL2, and a transmission layer TL may be positioned on the first opening OP1 of the first partition wall BK1.

The filling layer FL is between the partition walls BK1 and BK2 and the color filters CF1, CF2, and CF3, between the first color conversion layer CCL1 and the color filters CF1, CF2, and CF3, and the second color conversion layer CCL2 and the color filters CF1, CF2, and CF3, and between the transmission layer TL and the color filters CF1, CF2, and CF3.

The filling layer FL may contact one surface of the color conversion layers CCL1 and CCL2, the transmission layer TL, and the partition walls BK1 and BK2.

Also, the filling layer FL may contact one surface of the insulating layer IL3.

In the embodiment of FIG. 9, the position of the filling layer FL may be modified compared to the embodiments of FIG. 4.

FIG. 10 is similar to an embodiment of FIG. 7, except that the color change part CC according to the embodiments of FIG. 10 may include a first partition wall BK1 and a second partition wall BK2 positioned on the envelope layer ENC.

A first color conversion layer CCL1, a second color conversion layer CCL2, and a transmission layer TL may be positioned on the first opening OP1 of the first partition wall BK1.

The filling layer FL is between the partition walls BK1 and BK2 and the color filters CF1, CF2, and CF3, between the first color conversion layer CCL1 and the color filters CF1, CF2, and CF3, and the second color conversion layer CCL2 and the color filters CF1, CF2, and CF3, and between the transmission layer TL and the color filters CF1, CF2, and CF3.

The filling layer FL may contact one surface of the color conversion layers CCL1 and CCL2, the transmission layer TL, and the partition walls BK1 and BK2.

Also, the filling layer FL may contact one surface of the insulating layer IL3.

In the embodiment of FIG. 10, the position of the filling layer FL may be modified compared to the embodiments of FIG. 7.

According to an embodiment, in a process of combining the first substrate SUB1 on which the color conversion layers CCL1 and CCL2 are formed and the second substrate SUB2 on which the color filters CF1, CF2 and CF3 are formed, a material, for example, a filler, for forming the filling layer FL is provided on the first partition wall BK1 and the second partition wall BK2.

In such a process, the filling material is restricted in its movement by the second partition wall BK2, and a height difference between the filling layer FL positioned in the non-displayed area PA and the filling layer FL positioned in the displayed area DA may occur.

This height difference may be expressed or viewed as a stain at the edge of the display area DA. According to an embodiment, the second partition wall BK2 positioned in the non-display area PA includes the second part P2. In such an embodiment, since the filler may be allowed to smoothly move even in the non-display area PA to form a uniform thickness of the filling material, it may be possible to provide a filling layer FL with a uniform thickness. Accordingly, it is possible to limit stain expression on the edge of the display area DA.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device, comprising:
a substrate including a display area and a non-display area;
a transistor disposed on the substrate;
a light emitting diode disposed on the transistor and electrically connected to the transistor;
a color conversion layer and a transmission layer, which are disposed on the light emitting diode; and
a partition wall disposed on the light emitting diode,
wherein the partition wall comprises:
a first partition wall disposed in the display area between the color conversion layer and the transmission layer; and
a second partition wall disposed in the non-display area, wherein the second partition wall comprises:
a first part having a first length from a first end to a boundary of the display area and the non-display area; and
a second part having a second length from a second end to a boundary of the display area and the non-display area,
wherein the first length is greater than the second length.

2. The display device of claim 1, wherein
the first part protrudes further than the second part from a boundary of the display area and the non-display area in a plan view.

3. The display device of claim 1, wherein
the first partition wall defines a first opening in which the color conversion layer and the transmission layer are disposed, and
the second partition wall defines a second opening having a same shape as the first opening.

4. The display device of claim 1, wherein
the first part and the second part protrude from a boundary of the display area and the non-display area toward a first direction.

5. The display device of claim 4, wherein
the first part and the second part are alternately disposed along a second direction perpendicular to the first direction.

6. The display device of claim 1, further comprising:
a color filter disposed on the color conversion layer, the transmission layer and the partition wall.

7. The display device of claim 6, wherein
the color filter comprises
a first color filter disposed on the transmission layer,
a second color filter disposed on a second color conversion layer of the color conversion layer, and
a third color filter disposed on a first color conversion layer of the color conversion layer,
wherein the partition wall overlaps at least two selected from the first color filter, the second color filter, and the third color filter.

8. The display device of claim 7, wherein
the first color filter, the second color filter, and the third color filter continuously extend in the non-display area.

9. The display device of claim 3, further comprising:
a filling layer disposed between the light emitting diode and the color conversion layer and between the light emitting diode and the transmission layer.

10. The display device of claim 9, wherein
the filling layer fills the second opening.

11. The display device of claim 1, further comprising:
a column spacer disposed between the partition wall and the light emitting diode.

12. The display device of claim 1, wherein
the first partition wall defines a first opening in which the color conversion layer and the transmission layer are positioned, and
no opening is defined in the second partition wall.

13. The display device of claim 12, wherein:
the second partition wall continuously overlaps a color filter positioned in the non-display area.

14. The display device of claim 1, further comprising:
a filling layer disposed on the partition wall, the color conversion layer, and the transmission layer, and
a color filter disposed on the filling layer.

15. A display device, comprising:
a first substrate including a display area and a non-display area,
a transistor disposed on the first substrate,
a light emitting diode disposed on the first substrate and electrically connected to the transistor,
a color conversion layer and a transmission layer which are disposed on the light emitting diode, and
a partition wall disposed on the light emitting diode,
wherein the partition wall comprises:
a first partition wall disposed in the display area between the color conversion layer and the transmission layer, and
a second partition wall disposed in the non-display area,
wherein the second partition wall includes a protruding part and a recessed part in a plan view.

16. The display device of claim 15, further comprising:
an encapsulation layer disposed on the light emitting diode, and
a filling layer disposed between the color conversion layer and the encapsulation layer, and
wherein the filling layer fills the recessed part.

17. The display device of claim 15, wherein:
the first partition wall defines a first opening overlapping the color conversion layer and the transmission layer, and
the second partition wall defines a second opening having the same shape as the first opening.

18. The display device of claim 15, wherein:
the first partition wall defines a first opening overlapping the color conversion layer and the transmission layer, and
no opening is defined in the second partition wall.

19. The display device of claim 15, further comprising:
a second substrate overlapping the first substrate, and
a color filter disposed between the second substrate and the color conversion layer.

20. The display device of claim 19, further comprising:
a filling layer disposed between the color filter and the color conversion layer.
